(19) United States
(12) Patent Application Publication
(10) Pub. No.: US 2023/0345664 A1
(43) Pub. Date: Oct. 26, 2023

(54) THERMAL MANAGEMENT SYSTEMS AND METHODS FOR CELLULAR BASE STATION ENCLOSURES

(71) Applicant: CommScope Design & Integration UK Limited, Fife (GB)

(72) Inventors: Steven Zanft, Malton (GB); Michael Gardner, Malton (GB)

(21) Appl. No.: 18/020,684

(22) PCT Filed: Aug. 10, 2021
(86) PCT No.: PCT/EP2021/072288

§ 371 Date: Feb. 10, 2023

Related U.S. Application Data
(60) Provisional application No. 63/064,202, filed on Aug. 11, 2020.

(51) Int. Cl. H05K 7/20

(52) U.S. Cl. CPC H05K 7/20209; H05K 7/20136

(57) ABSTRACT

Base station enclosure and the equipment therein may generate excess amounts of heat, and temperatures within the base station enclosure may be managed via cooling equipment. To better manage the temperature, a system is provided comprising: a temperature sensor and cooling fan; and a controller comprising a processor, a temperature input port communicatively coupled to the temperature sensor, and a fan output port communicatively coupled to the cooling fan. The processor may be configured to: receive a signal indicating temperature data sensed by the temperature sensor; and control a fan duty of the cooling fan based on the received temperature data received from the temperature sensor via the temperature input port and using proportional and integral control.

### CROSS-REFERENCE TO RELATED APPLICATION(S)

The application claims priority to U.S. Provisional Application No. 63/064,202, filed on Aug. 11, 2020, with the United States Patent and Trademark Office, and the entire contents of the above-identified application(s) are incorporated by reference as if set forth herein.

### TECHNICAL FIELD

The present disclosure relates generally to cellular base station enclosures or cabinets, and more specifically to providing thermal or temperature management of the enclosures or cabinets.

### BACKGROUND

Cellular communications systems are known in the art. In a typical cellular communications system, a geographic area is divided into a series of regions that are referred to as “cells,” and each cell is served by a base station. Typically, a cell may serve users who are within a distance of, for example, 1-20 kilometers from the base station, although smaller cells are typically used in urban areas to increase capacity. The base station may include baseband equipment, radios, and antennas that are configured to provide two-way radio frequency (“RF”) communications with fixed and mobile subscribers (“users”) that are positioned throughout the cell.

At the base station, radios may receive digital information and control signals from the baseband unit and may modulate this information into radio frequency (“RF”) signals that are then transmitted through the antennas. A radio also receives RF signals from antennas and demodulates these signals and supplies them to the baseband unit. The baseband unit processes demodulated signals received from the radio into a format suitable for transmission over a backhaul communications system. The baseband unit also processes signals received from the backhaul communications system and supplies the processed signals to the radio. A power supply is also provided that generates suitable power signals, such as direct current power signals, for powering the baseband unit and the radio. The power supply is typically tied to main or grid power, although in some instances the power supply may be powered by a battery or other electrical power source either as a primary or backup power source.

Typically, some portion of the base station equipment is stored within a cabinet or other enclosure, which is located at the base of a tower or other structure. A remainder of the base station equipment is typically mounted at locations on the tower, e.g., at the top of the tower. For example, the antennas are typically mounted at the top of the tower, and in recent installations “remote” radios (remote radio heads, or RRH) have also been mounted at the top of the tower for communication efficiency purposes and to avoid signal loss. The power supply, the baseband unit, and other equipment are typically located at the base of the tower, typically within a metal cabinet.

The base station equipment located within the cabinet may generate large amounts of heat, which may cause an internal cabinet temperature to rise. If left unchecked or uncontrolled, the internal temperature may rise well in excess of 50° C., which may result in reduced functionality of the base station equipment, or even complete failure of the equipment. Ambient or external temperatures may also cause temperatures within the cabinet to rise, and in the summer months may cause internal temperatures that impact performance of the base station equipment. Therefore, the internal temperature must be maintained or controlled for the network to operate. Typically, this maintenance or controlling is done by providing cooling equipment, though in some locations a heater may also be deployed (as base station equipment may also have reduced or no functionality in low temperatures).

Throughout the mobile telecommunications industry, it has been reported that up to 45% of all power consumption in base station equipment is used in cooling of the equipment contained within. Some estimates show that cooling of base station equipment is on the order of 0.5%-1% of total global power usage.

There has been an increasing demand for wireless communication systems and a corresponding demand to provide greater coverage areas. Consumers now typically expect cell coverage and reception wherever they travel, including in urban, suburban, exurban, and rural locations. As such, the large power consumption by cooling equipment at base stations is generally increasing in proportion with this increasing demand, which results in increased operating expenditures for cellular network operators and an increasing contribution to global energy consumption.

### SUMMARY

Various aspects of the present disclosure provide thermal management systems and methods for cellular base station enclosures. For example, some embodiments according to the present disclosure provide systems that include: a base station enclosure comprising a temperature sensor and cooling fan. and a controller comprising a processor, a temperature input port communicatively coupled to the temperature sensor, and a fan output port communicatively coupled to the cooling fan. The processor may be configured to: receive a signal indicating temperature data sensed by the temperature sensor; and control a fan duty of the cooling fan based on the received temperature data received from the temperature sensor via the temperature input port and using proportional and integral control.

In some of the embodiments, the cooling fan is a first cooling fan of a plurality of cooling fans, wherein the fan output port is a first fan output port of a plurality of fan output ports, and wherein each cooling fan of the plurality of cooling fans is communicatively coupled to the controller via a respective fan output port of the plurality of fan output ports.

In some of the embodiments, the controller is configured to communicate with at least two of the cooling fans via a single channel.

In some of the embodiments, the controller is configured to communicate with each cooling fan independently.

In some of the embodiments, the controller is configured to provide a web application that provides the temperature data from the temperature sensor for display on a remote device.

In some of the embodiments, the web application comprises a graphical user interface.

In some of the embodiments, the web application comprises a user control configured to receive input for at least one property of the controller.

In some of the embodiments, the base station enclosure comprises cellular base station equipment, and wherein the controller is configured to receive temperature data indicating a temperature of the cellular base station equipment.

In some of the embodiments, the processor is further configured to detect an overriding condition present in the base station enclosure and override the fan duty controlled using the proportional and integral control.

In some of the embodiments, the overriding condition is an excess of hydrogen or smoke present within the base station enclosure.

As another example, some embodiments according to the present disclosure provide methods that include: receiving, by a processor, a signal indicating temperature data sensed by a temperature sensor located within a base station enclosure; controlling, by the processor and using proportional and integral control, a fan duty of a cooling fan located within the base station enclosure, based on the temperature data received from the temperature sensor; detecting an overriding condition present in the base station enclosure; and overriding the fan duty controlled using the proportional and integral control.

In some of the embodiments, the overriding condition is an excess of hydrogen or smoke present within the base station enclosure.

In some of the embodiments, the overriding condition is a presence of a person within the base station enclosure.

In some of the embodiments, the processor is located within the base station enclosure.

As another example some embodiments according to the present disclosure provide systems that include: a base station enclosure comprising a plurality of temperature sensors and a plurality of cooling fans; and a controller comprising a processor, a plurality of temperature input ports each communicatively coupled to a respective temperature sensor, and a plurality of fan output ports communicatively coupled to a respective cooling fan. The processor may be configured to: receive a signal indicating temperature data sensed by each temperature sensor; and control a fan duty of each cooling fan based on the received temperature data and using proportional and integral control.

In some of the embodiments, the controller is configured to communicate with at least two of the cooling fans via a single channel.

In some of the embodiments, the controller comprises a data storage, and wherein the processor is configured to record the temperature data to the data storage.

In some of the embodiments, the controller comprises a main board and an extension board coupled via an extension port of the main board.

In some of the embodiments, the base station enclosure comprises cellular base station equipment, and wherein the controller is configured to receive temperature data indicating a temperature of the cellular base station equipment.

In some of the embodiments, the controller is configured to provide a web application that provides the temperature data from each temperature sensor for display on a remote device.

Various example embodiments will be described more fully hereinafter with reference to the accompanying drawings, in which some examples of embodiments are shown. The shown examples of the embodiments should not be construed as being limiting of the present disclosure. Although a few example embodiments are described and shown herein, those skilled in the art will readily appreciate that many modifications are possible in the example embodiments without materially departing from the present inventive concepts.

### BRIEF DESCRIPTION OF THE FIGURES

FIGS. 1A-E illustrate an example of an enclosure for base station equipment, according to some of the inventive concepts disclosed herein.

FIGS. 2A and 2B illustrate an example cooling system controller.

FIG. 3 illustrates an example add-on module that may be used with the cooling system controller of FIGS. 2A and 2B.

FIG. 4 is a block diagram of various components of computing devices, which may be used to implement components of the cooling system controller.

FIG. 5 is a flowchart diagram illustrating an example method used by components of the cooling system controller to control fan speed and/or duty cycle according to a proportional-integral-derivative (PID) control methodology.

FIGS. 6A-6G are flowchart diagrams illustrating examples of override conditions used by components of the cooling system controller to override the PID control methodology of FIG. 5.

FIG. 7 is an example illustration of a user interface (UI) “dashboard” that provides data and/or controls to a user to monitor and/or control operation of a cooling system controller.

FIGS. 8A, 8B, and 9 are graphs illustrating a difference between non-PID control of cooling equipment and PID control of cooling equipment.

### DETAILED DESCRIPTION

Generally speaking, forced air cooling is not a new technology, and has been deployed in base station enclosures. However, the present disclosure is based on a recognition that there are potential improvements to control systems which govern these forced air cooling systems.

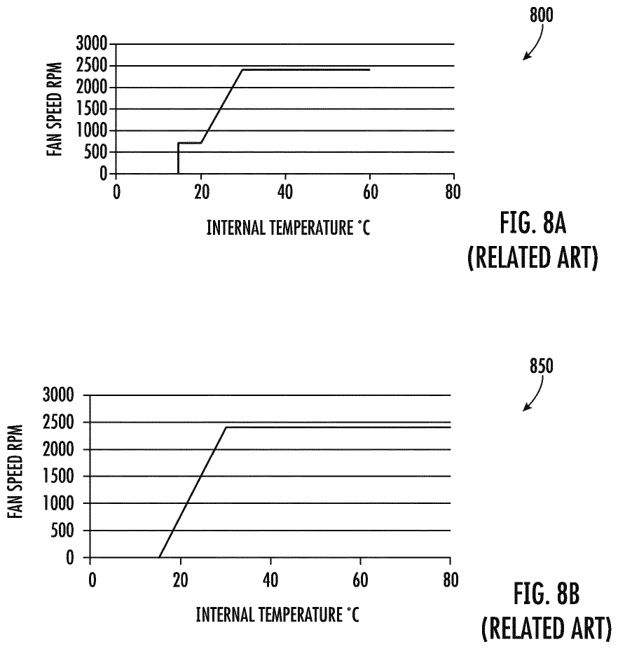

FIG. 8A shows a graph 800 illustrating one way in which a conventional cooling control system may control fan speed responsive to data indicative of an internal temperature of a base station enclosure. Given an input internal temperature, a controller may determine a fan speed profile by referring a ‘lookup table’ stored in its system memory. This ‘lookup table’ and the fan speed profile drawn therefrom are pre-determined through intensive testing in a laboratory environment. As such, the ‘lookup table’ is not adaptable to different configurations of base station equipment within an enclosure; new configurations of equipment and/or new enclosures may require new rounds of laboratory testing.

As seen in FIG. 8A, the fan speed profile, which is graphically represented in graph 800, may be configured to cause the controller to start the fans at an ambient temperature of approximately 15° C., and set the fans at full speed at 30° C. For ambient temperatures between 15° C. and 20° C., the fan speeds are set at approximately 750 RPM. From 20° C. to 30° C., there is a linear relationship between the internal temperature and the fan speed.

FIG. 8B shows a graph 850 illustrating another way a cooling control system may control fan speed responsive to data indicative of an internal temperature of a base station enclosure. The fan speed profile graphically represented in FIG. 8B may be a simple linear relationship between the internal temperature and the fan speed. The fan speed profile may replicate the starting and ending points of the fan speed profile of FIG. 8A, and be configured to cause the controller to start the fans at an ambient temperature of approximately 15° C., and set the fans at full speed at 30° C. For ambient temperatures between 15° C. and 30° C., there is a linear relationship between the internal temperature and the fan speed. However, in most worldwide climates, and particularly in climates within the United States and the United Kingdom, fans controlled by the fan speed profile graphically represented in FIG. 8A or the fan speed profile graphically represented in FIG. 8B will be generally operating at fan speeds of at least 30% of their rated maximum speed throughout the year.

The present disclosure describes the deployment of proportional-integral-derivative (PID) control systems within base station enclosures. As is known, a PID controller repeatedly and continuously calculates a difference between a set point (here, the desired internal temperature of the base station enclosure) and the measured internal temperature. The controller may control one or more fans or other cooling equipment responsive to this calculated difference and based on calculated proportional, integral, and/or derivative terms. For example, if the difference between the set point and the measured temperature is both large and positive, then the proportional term will be correspondingly large and positive. If there is are residual differences after the application of proportional control, the integral term may add an effect that attempts to eliminate the residual differences. The derivative term seeks to introduce a controlling or dampening effect based on the current rate of change, for example to avoid significantly “overshooting” the desired set point.

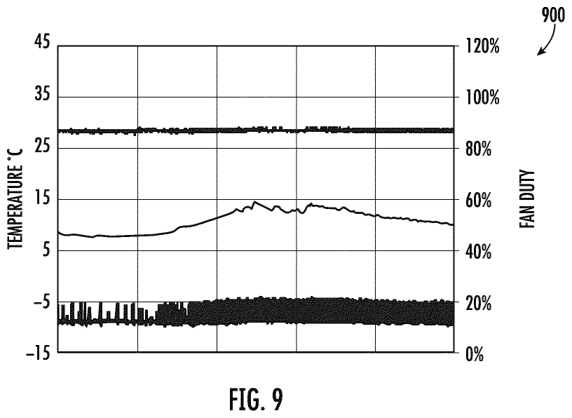

FIG. 9 provides graph 900, respectively, showing the usage of PID control in testing conditions. As discussed above, PID control uses a set point to drive the system duty, and in each of the respective testing environments of FIGS. 9A and 9B, the internal temperature set point was set to 27° C. In mild conditions, where the ambient or external temperature fluctuated between 5° C. and 15° C., the fan duty was significantly lower (e.g., approximately 20%) than the conventional fan speed profiles discussed above with respect to FIGS. 8A and 8B. Advantageously, in such conditions, a PID controlled system (e.g., the system corresponding to FIG. 9) does not start consuming energy until the internal temperature is approximately 26° C., at which point the conventional system (e.g., systems corresponding to FIGS. 8A-8B), a cost difference of £681 or $900 per year (in 2020). Additionally, the conventional systems reach full power output at 30° C., whereas the PID-controlled system does not reach full speed until 34° C., further resulting in cost and power savings.

Examples of embodiments of base station enclosures having PID-controlled cooling systems and equipment, such PID-controlled cooling systems and equipment, and methods of operating such PID-controlled cooling systems and equipment will now be described. Although methods and devices herein discuss PID-control, in some embodiments one or more of the P, I, and D values may be set to zero. For example, the derivative value D, which may be susceptible to noise, may be set to zero. Thus, as used herein, the term “PID control” may include one, two, or three of proportional, integral, and derivative control.

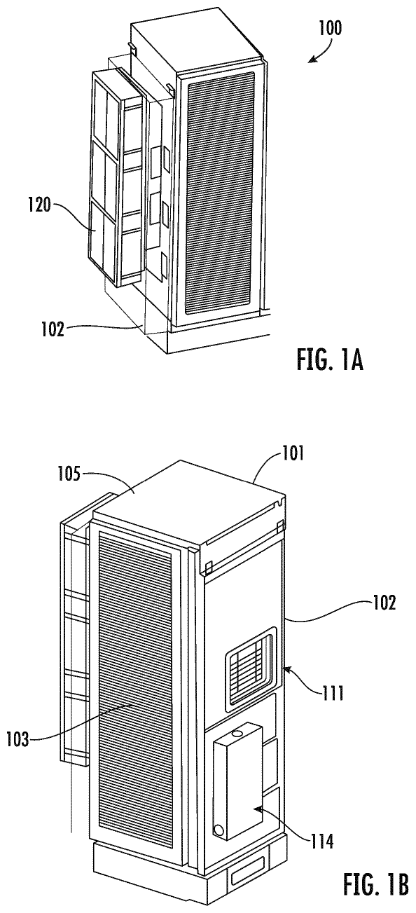

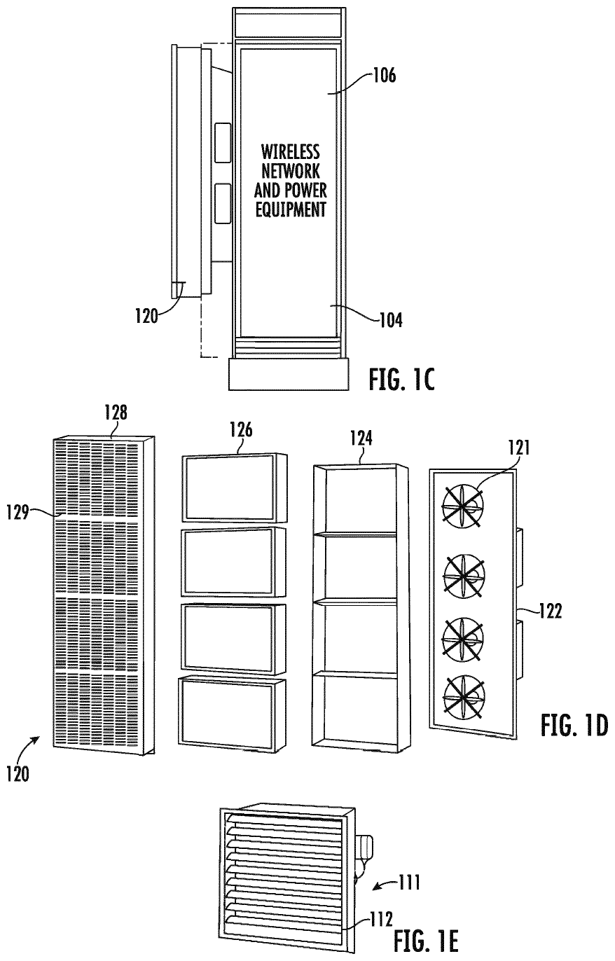

FIGS. 1A-1E illustrate an enclosure 100 and components thereof. The enclosure 100 may be referred to herein as an electronics cabinet, cabin, or base station enclosure. The enclosure 100 illustrated in FIGS. 1A-1E is merely one of many possible examples, and the present disclosure is not limited to the length, width, or height of the example enclosure 100 illustrated in FIG. 1.

The enclosure module is generally rectangular and box-shaped, with a rear wall 101, two side walls 102, a front wall 103, and a ceiling 105. These structures define an interior cavity 104. As can be seen in FIG. 1C, the interior cavity 104 may be filled with electronic equipment and accessories. Examples of such equipment/accessories include radios, multicarrier power amplifiers (MCPA), power supplies, batteries, and wireless cell site backhaul equipment.

The front wall 103 can be removed or, more commonly, can be attached as a door 103 via a hinge on the side thereof to swing open and closed. In either instance, the front wall 103 is configured to allow selective access to the interior cavity 104.

As best seen in FIG. 1B, in some embodiments, one of the exterior side walls 102 of the enclosure 100 may include a cooling exhaust system 111 that employs an adjustable louvered opening with louvers 112 (see also FIG. 1E). The side wall 102 may also include an AC power input panel 114 to provide power to the enclosure 100 and the equipment therein.

As best seen in FIGS. 1A and 1D, one of the exterior side walls 102 of the enclosure 100 may be configured to provide a mounting location for a cooling system 120. The cooling system 120 may include a fan assembly 122 comprising one or more fans 121 (four fans 121 shown in FIG. 1D), as well as components such as a filter holder 124, filters 126, and an outer cover 128 with vents 129. The side wall 102 may include an opening (not shown) near a side edge thereof to provide communication to the interior cavity 104 of the enclosure 100 to which the cooling system 120 is mounted.

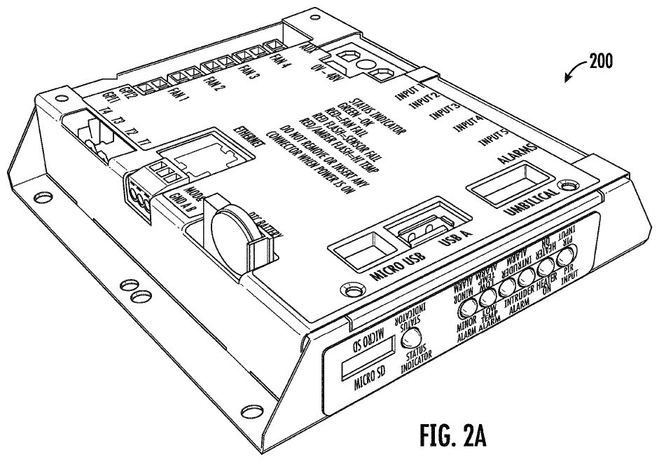

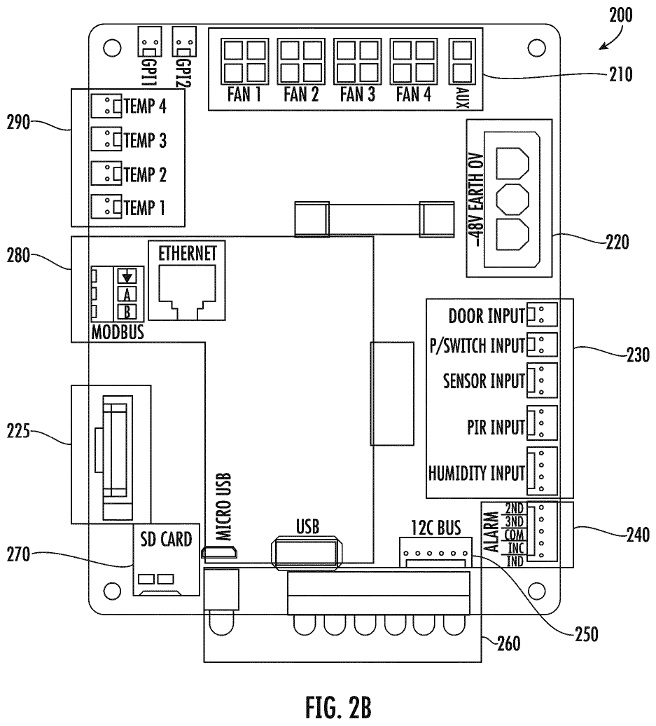

The cooling system 120 and the cooling exhaust system 111 may be controlled via a controller 200 (FIG. 2, below). The controller 200 is typically connected (either directly or wirelessly) to one or more temperature sensors 106 within the interior cavity of the enclosure 100. Based on temperature readings from the sensors 106, the controller 200 may control one or more operating parameters of the cooling system 120; these may include activation/deactivation of one of the fans 121 of the fan assembly 122, and/or adjusting the speed of the fans 121. In addition, the controller 200 may control flaps, doors, shutters, dampers or the like associated with the cooling system 120 and the cooling exhaust system 111 to regulate air flow within the enclosure 100. The controller 200 may also control the louvers of the louvered opening 112 to adjust their position and, in turn, regulate air flow. The controller 200 may be located within the cooling system 120, within the enclosure 100, or any other appropriate location.

FIGS. 2A and 2B show an example controller 200, which as discussed above may be configured to control fans 121 by a PID control methodology and a configurable set point value, rather than fixed fan profile curves. The controller 200 may comprise one or more fan ports 210 configured to communicate signals (power and/or control signals) to the fans 121. The controller 200 may be configured with multi-channel capability. Each fan 121 can be independently controlled, and/or two or more fans may be grouped together and controlled on a single channel. Independent control over each of the fans 121 allows finer tuning of the cooling requirements.

Each of the channels may be controlled using proportional and integral control. In some embodiments, the proportional control may include multiplying the difference between a channel set point and the actual internal temperature by a predetermined gain, or ‘P value.’ The integral control may calculate the sum of the difference between the channel set point and the actual internal temperature over time. The longer that the difference between the channel set point and the actual internal temperature is present, the greater the integral action is to reduce the difference.

The controller 200 may also include temperature input ports 290 configured to receive temperature signals from temperature sensors (not shown) located within the enclosure. These temperature sensors may provide “ambient” temperature signals (e.g., the temperature of the air within the enclosure 100) and/or may provide signals indicative of a temperature of one or more pieces of base station equipment (e.g., an internal temperature of a baseband unit, an internal temperature of a battery). The controller 200 may be configured with a definable alarm set point for each of the temperature sensors 290, and as such equipment within the enclosure 100 may be monitored. As will be discussed further below, if one or more of these definable alarm set points are exceeded (e.g., indicative that equipment may be above or below its operating temperature), the controller 200 may communicate this to a remote location.

The controller 200 may also include environmental input ports 230 configured to receive signals from sensors (not shown) located at various locations within the enclosure. For example, the environmental input ports 230 may include a port configured to receive a signal indicating whether door or panel 103 is opened, whether motion is detected by a passive infrared (PIR) sensor, and/or data from other sensors, such as humidity sensors.

The controller 200 may be powered via power ports 220, and may be configured to receive a voltage provided by a rectifier that also powers other equipment within the enclosure 100. The controller may be provided with various communication components, including visual communication components 260 that may be configured to communicate status to a local user (e.g., light emitting diodes or other visual display devices that communicate information to an on-site engineer configuring equipment within the enclosure). Other communication components include alarm ports 240, which may be configured to communicate alarm status to a local or remote user; and communication interface 280, which may include, e.g., a MODBUS port that is configured to allow the controller 200 to integrate into building management systems (BMS). An Ethernet port may also be provided in the communication interface 280 to permit the controller 200 to communicate with one or more remote devices (e.g., computing devices or servers) via an external network, such as the Internet. The communication interface 280 may also have ports, such as Universal Serial Bus ports, that allow the controller 200 to be programmed locally.

As discussed further below, in some embodiments the controller 200 may be programmed to take into account energy usage considerations and may be configured to use a setback temperature during time periods of high grid usage. A setback temperature may be higher or lower than the desired internal temperature, which may be used as the temperature set point to avoid excess electrical energy tariffs or costs during the time periods of high usage. These time periods may be communicated or predetermined and programmed into the controller 200. The controller 200 may check these time periods against a real-time clock (RTC); to ensure that the controller 200 properly adheres to the setback time periods, a backup battery 225 may be provided.

The controller 200 may be configured to store operational data, such as time, date, channel set point, internal temperature, external temperature, additional temperature inputs, the P, I, & D values for each channel, an overall fan duty % for each channel, the RPM of each active fan, and alarm statuses and set point value. These variables may be recorded periodically (e.g., every 10 seconds, every minute) within memory. In some embodiments, a Secure Digital (SD) card may be used as the memory.

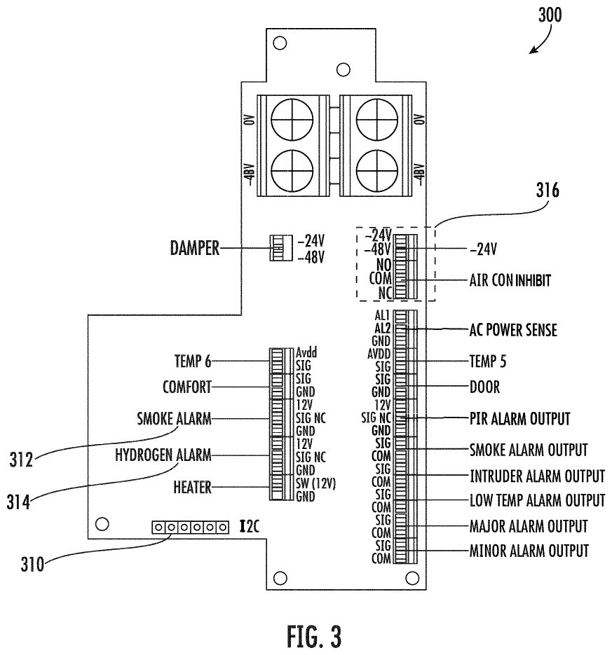

The controller 200 may also include an extension interface 250, which in some embodiments may be I2C (Inter-Integrated Circuit) which may be configured to connect with one or more expansion boards. An example of an expansion board is provided in FIG. 3 and expansion board 300 thereof. As can be seen in FIG. 3, input and/or output ports for additional alarms such as a smoke alarm 312, a hydrogen alarm 314 may be provided on an expansion board. Additionally or alternatively, ports 316 for communicating with an air conditioning unit or other external cooling system to which the controller 200 can “hand over” control are provided. Different expansion boards may be provided, thus enabling customization of the controller 200 to accommodate different enclosures and/or equipment therein. The extension interface 250 of the controller 200 may communicate with the expansion board 300 via an extension interface 310 of the expansion board 300.

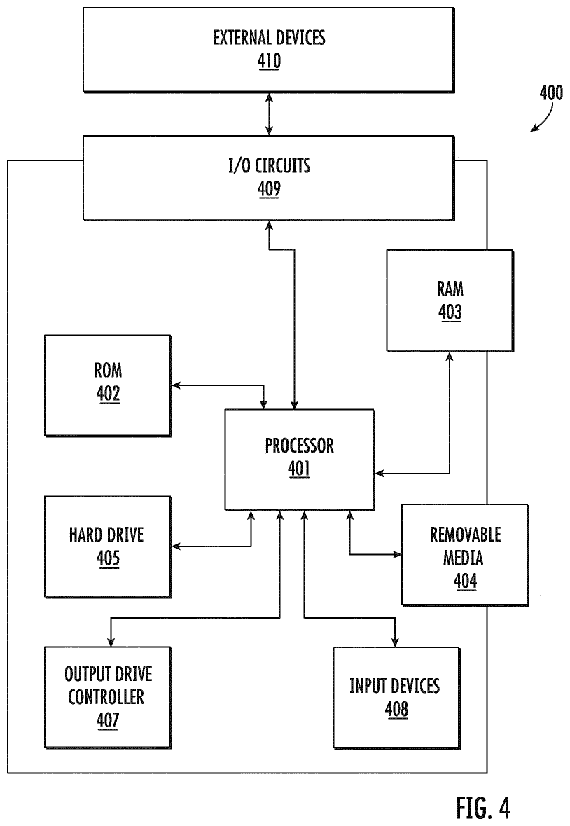

FIG. 4 illustrates hardware elements that can be used in implementing any of the various computing devices and boards discussed above. In some aspects, general hardware elements may be used to implement the various devices discussed herein, and those general hardware elements may be specially programmed with instructions that execute the algorithms discussed herein. In special aspects, hardware of a special and non-general design may be employed (e.g., ASIC or the like). Various algorithms and components provided herein may be implemented in hardware, software, firmware, or a combination of the same.

A computing device 400 may include one or more processors 401, which may execute instructions of a computer program to perform any of the features described herein. The instructions may be stored in any type of computer-readable medium or memory, to configure the operation of the processor 401. For example, instructions may be stored in a read-only memory (ROM) 402, random access memory (RAM) 403, removable media 404, such as a Universal Serial Bus (USB) drive, compact disk (CD) or digital versatile disk (DVD), floppy disk drive, or any other desired electronic storage medium. Instructions may also be stored in an attached (or internal) hard drive 405. The computing device 400 may be configured to provide output to one or more output devices, and may include one or more output device controllers 407 to provide this output. Inputs, including user inputs, may be received via input devices 408, such as an accelerometer, a remote control, keyboard, mouse, touch screen, microphone, or the like. The computing device 400 may also include input/output circuits 409 which may include circuits and/or devices configured to enable the computing device 400 to communicate with external devices 410. The input/output circuits 409 may enable the computing device 400 to communicate with an external device 410.

As discussed above with respect to FIG. 2, the components of computing device 400 need not be located in a single housing (although they may be in some embodiments) and may be located in different locations. The components of a computing device 400 may engage in bidirectional or unidirectional communication via one or more wired or wireless interfaces (e.g., a wired bus, wireless protocol transceivers that are configured to communicate using Bluetooth, Wi-Fi, Zigbee, Z Wave, Sigfox®, LoRa®, RPMA, Weightless, NB-IoT, cellular Low Power Wide Access (LPWA), or other networks or communication protocols, and other wired or wireless interfaces).

The controller 200 may include various software components. For example, the controller 200 may include (in the storage 405) a Unix or Linux based operating system and software components compatible with such an operating system. In some embodiments, the controller 200 may instantiate or run a web and/or application server, and may be configured to serve a website or web application via the server. The web application may include a graphical user interface (GUI) that provides data and/or controls to a user (for example, over the Internet or over an Internet-accessible web page) to monitor and/or control operation of the controller 200. The web application may be password protected. This software may permit the controller 200 to be programmed or configured remotely, without requiring specialized software at the remote device and/or a specialized cabling connection. Additionally, using a Unix or Linux based core may enable the controller 200 to be expanded as needed.

In some embodiments, the web application can be used remotely to not only observe data recorded from within the enclosure, but may be used to modify settings such as set points of alarms. In some embodiments, either in addition to the web-based graphical user interface or in the alternative to such a GUI, the controller 200 may be configured to transmit and receive messages communicated over a wireless network (e.g., a cellular network) to a remote device. For example, the controller 200 may be configured to communicate short messages (SMS) and/or respond to commands communicated using SMS.

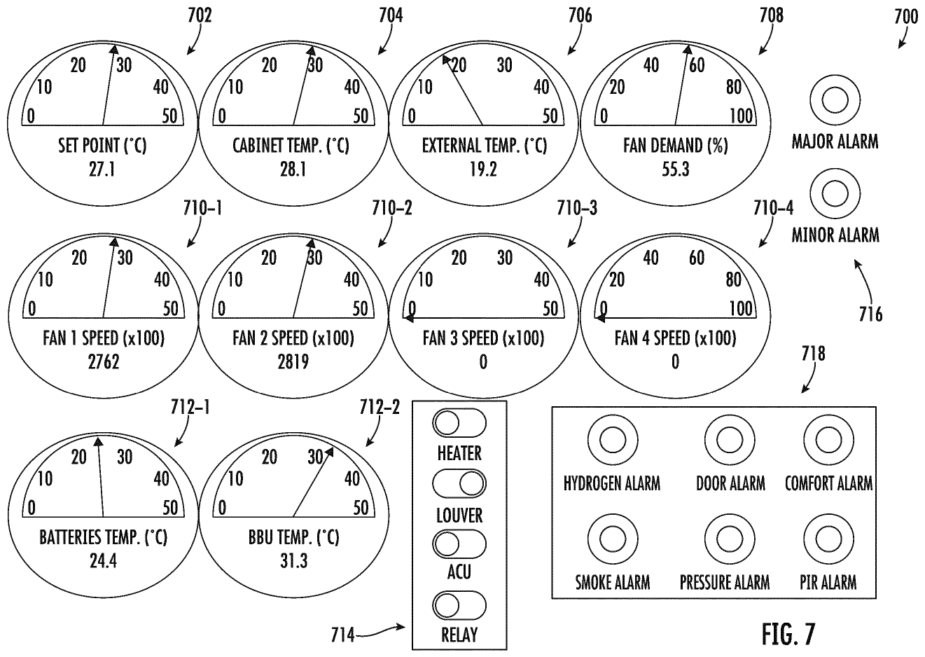

FIG. 7 is an example of a user interface dashboard 700 in accordance with the above. The dashboard 700 may be generated programmatically by a web application being executed by the controller 200, and may be accessed via a web browser running on a remote computing device (e.g., laptop, desktop, smartphone, tablet, or the like).

As discussed above, the controller 200 may have multi-channel capabilities and may communicate with the fans 121 of the enclosure 100 either independently from each other, or grouped together. The dashboard 700 may represent a single channel; in this example, two fans (e.g., fan 1 and fan 2) are controlled by the channel. The dashboard 700 may include representations of the desired set point 702, the internal temperature 704, the external temperature 706, the current fan duty or demand 708, fan speeds 710, one or more other temperature readings 712, as well as status or controls for components of the cooling system 120 and/or the cooling exhaust system 111. Alarm signals 716 and 718 may also be provided, either at a high level (e.g., “major” or “minor” alarms) and/or for specific observed components or situations.

The layout of the dashboard 700 is merely an example, and data represented graphically in dashboard 700 may be represented in any one of a number of different ways in various example embodiments. In some embodiments, users of the dashboard 700 may be able to customize and/or change how data is presented via the dashboard 700.

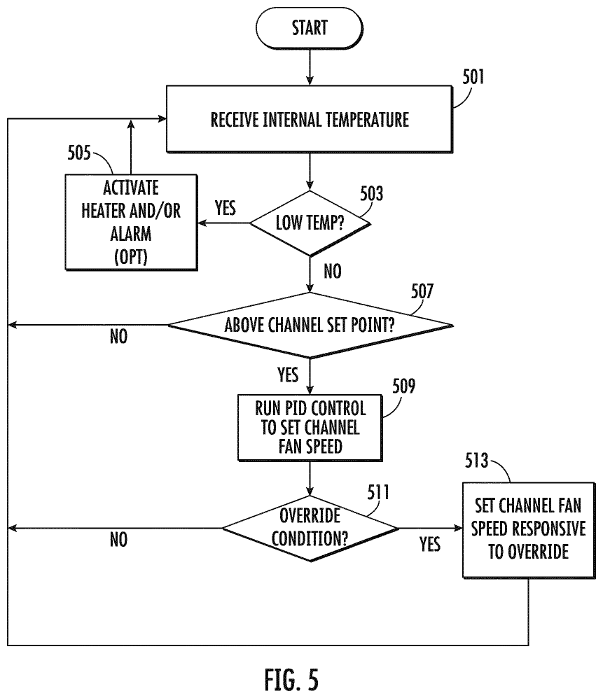

In accordance with the above, FIG. 5 illustrates a process by which controller 200 may control operation of one or more cooling fans and/or thermal equipment that provide temperature control of a base station enclosure. The method illustrated in FIG. 5 may commence (e.g., for each channel if the controller 200 is operating in multi-channel mode) at operation 501, in which the controller 200 (or a processor thereof) may receive temperature data from a temperature sensor (e.g., temperature sensor 106). In operation 503, the temperature data is compared with a low temperature threshold. If the data indicates that the temperature within the enclosure 100 is below the low temperature threshold (YES branch from operation 503), then a heater may be activated and/or an alarm may be raised in operation 505, as this may indicate that low temperature conditions are present (either due to low external temperatures, or failed equipment within the enclosure).

If, however, the temperature is above the low temperature threshold (NO branch from operation 503), then next the temperature data is compared with the channel set point (operation 507). If the temperature data is below the channel set point (NO branch from operation 507), then a change to the fan speed for the fans controlled by that channel may not be required at the present time. Otherwise (YES branch from operation 507), the current temperature within the enclosure is greater than the channel set point, and PID control may be used to set the fan speed for one or more fans communicating with the controller via the channel (operation 509).

In some instances or situations, it may be desired to override the fan speed because an override condition is present. The controller 200 may detect whether an override condition is present (operation 511). If no condition is present (NO branch from operation 511), then the controller 200 may return to operation 501 and await further data. On the other hand, if an override condition is present (YES branch from operation 511), then the controller may set the fan speed for one or more fans communicating with the controller via the channel based on the override condition (operation 513).

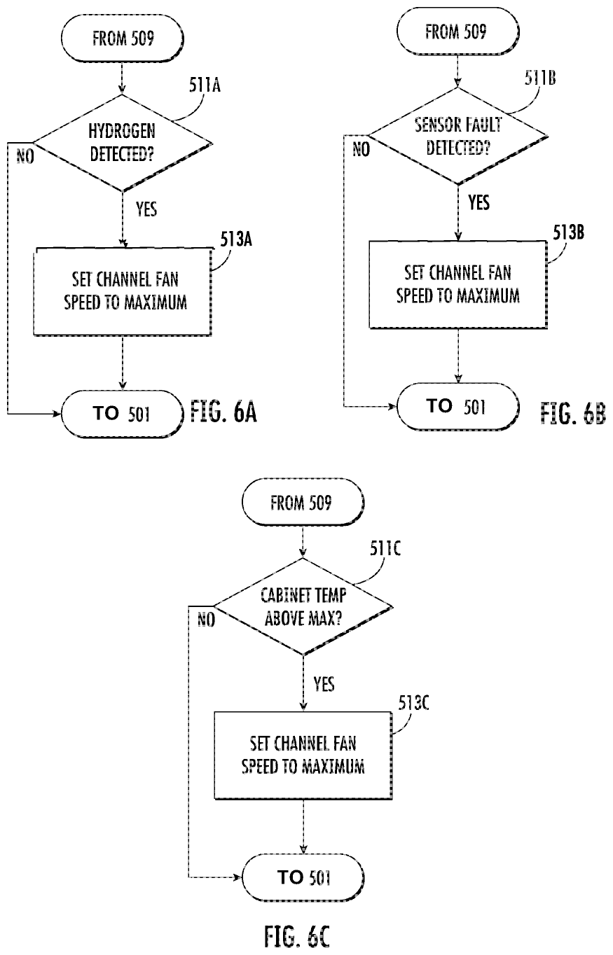

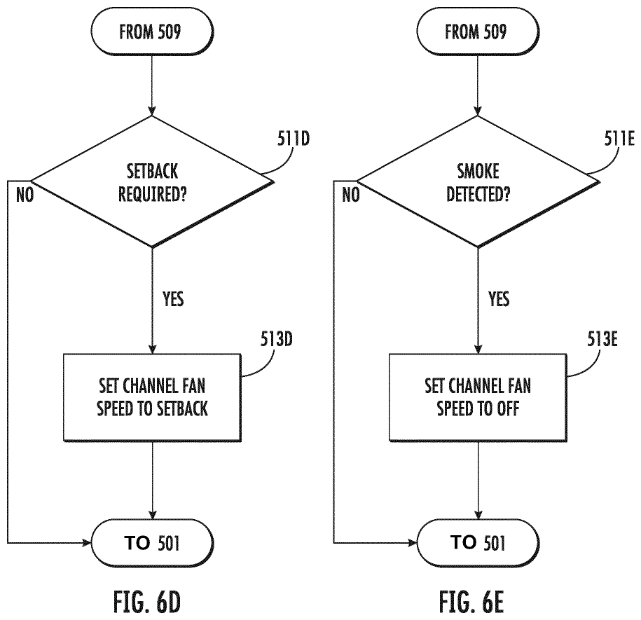

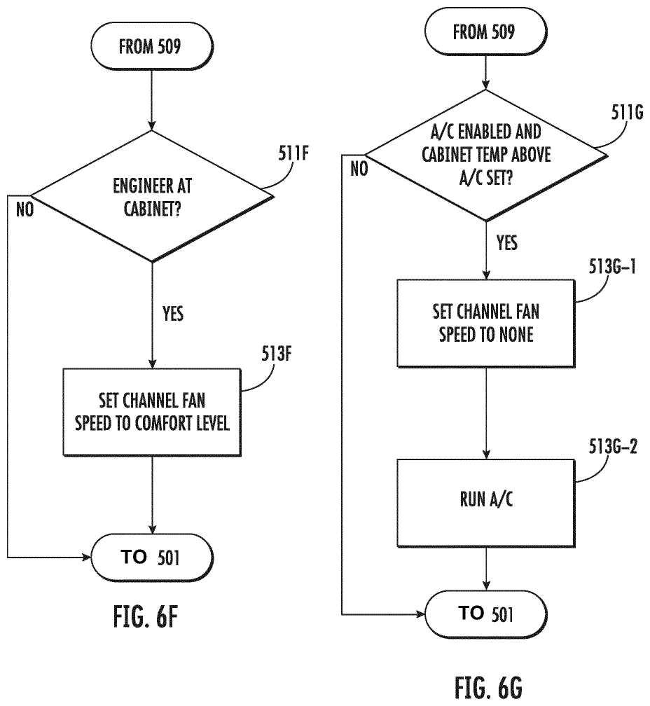

FIGS. 6A-6G give examples of override conditions. Each of the override conditions described in FIGS. 6A-6G (as well as others) may be checked either in parallel or serially in any other.

In FIG. 6A, an override condition may be the presence of hydrogen, which may indicate a failure within a battery or other hydrogen-containing component within the enclosure. Clearing the hydrogen from the enclosure may be important to avoid a fire or explosion. As such, a hydrogen sensor may detect whether an amount of hydrogen present within the enclosure exceeds a predetermined threshold (operation 511A). If so (YES branch from operation 511A), then the fan speed may be set to a maximum value to clear the hydrogen from the enclosure (operation 513A). If not, (NO branch from operation 511A), then the controller 200 may return to operation 501 and await further data and/or another override condition may be checked.

In FIG. 6B, an override condition may be the presence of a sensor fault, which may indicate a failure of a component within the enclosure. The controller may detect whether a sensor fault is present within the enclosure (operation 511B). If so (YES branch from operation 511B), then the fan speed may be set to a maximum value to ensure that the equipment within the enclosure is maintained at an appropriate temperature (operation 513B). If not, (NO branch from operation 511A), then the controller 200 may return to operation 501 and await further data and/or another override condition may be checked.

In FIG. 6C, an override condition may be the temperature data indicating that the temperature within the enclosure is above a predetermined maximum. The controller may detect whether the temperature within the enclosure is above a predetermined maximum (operation 511C). If so (YES branch from operation 511C), then the fan speed may be set to a maximum value to ensure that the equipment within the enclosure is maintained at an appropriate temperature (operation 513C). If not, (NO branch from operation 511C), then the controller 200 may return to operation 501 and await further data and/or another override condition may be checked.

In FIG. 6D, an override condition may be that a setback time period in which the temperature is permitted to exceed the defined set point to accommodate grid usage and/or handle peak energy situations. The controller may detect whether the current time is within a setback time period (operation 511D). If so (YES branch from operation 511D), then the fan speed may be set to a value responsive to the setback (operation 513D). If not, (NO branch from operation 511D), then the controller 200 may return to operation 501 and await further data and/or another override condition may be checked.

Related to FIG. 6D, though not shown in the figures, it may be that in some instances or situations, an override condition may be that a reduced noise period in which the temperature is permitted to exceed the defined set point to avoid generating excess noise, as the fans may be quite loud when spinning at higher speeds. Such an override condition would be handled similarly to FIG. 6D. If a reduced noise period is ongoing (YES branch from operation 511D), then the fan speed may be set to a value responsive to the reduced noise period (operation 513D). If not, (NO branch from operation 511D), then the controller 200 may return to operation 501 and await further data and/or another override condition may be checked.

In FIG. 6E, an override condition may be the presence of smoke, which may indicate a fire within the enclosure. A smoke detector may detect whether an amount of smoke present within the enclosure exceeds a predetermined threshold (operation 511E). If so (YES branch from operation 511E), then the fan speed may be turned off to avoid exacerbating or worsening a fire (if present) (operation 513E). If not, (NO branch from operation 511E), then the controller 200 may return to operation 501 and await further data and/or another override condition may be checked.

In FIG. 6F, an override condition may be that an engineer or technician is present at the enclosure. Because the fans may be quite loud when spinning at higher speeds, the temperature may be permitted to exceed the defined set point to accommodate the comfort and safety of the present engineer. The controller may detect whether the engineer is present, either based on an explicit signal from the engineer or based on detecting the presence of the engineer (via a PIR sensor or other sensor). If so (YES branch from operation 511F), then the fan speed may be set to a value responsive to the comfort of the engineer (operation 513F). If not, (NO branch from operation 511F), then the controller 200 may return to operation 501 and await further data and/or another override condition may be checked.

In FIG. 6G, an override condition may be that an air conditioning unit may be present and enabled, and that an internal temperature of the enclosure may be greater than an air conditioning set point. If so (YES branch from operation 511G), then the fan speed may be turned off to avoid duplicative or unnecessary cooling (operation 513G-1), and the air conditioning unit may be started (operation 513G-2. If not, (NO branch from operation 511G), then the controller 200 may return to operation 501 and await further data and/or another override condition may be checked.

Aspects of the present disclosure have been described above with reference to the accompanying drawings, in which embodiments of the present disclosure are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, operations, elements, and/or components, but do not preclude the presence or addition of one or more other features, operations, elements, components, and/or groups thereof.

Aspects and elements of all of the embodiments disclosed above can be combined in any way and/or combination with aspects or elements of other embodiments to provide a plurality of additional embodiments.

1. A system comprising:
a base station enclosure comprising one or more temperature sensors and one or more cooling fans; and
a controller comprising a processor, one or more temperature input ports communicatively coupled to the one or more temperature sensors, and one or more fan output ports communicatively coupled to the one or more cooling fans;
wherein the processor is configured to:
receive a signal indicating temperature data sensed by the one or more temperature sensors; and
control a fan duty of the one or more cooling fans based on the received temperature data received from the temperature sensor via the temperature input port and using proportional and integral control.

2. The system of claim 1, wherein the one or more cooling fans comprises a first cooling fan of the cooling fans, wherein the one or more fan output ports is a first fan output port of the output ports, and wherein each cooling fan of the one or more cooling fans is communicatively coupled to the controller via a respective fan output port of the one or more fan output ports.

3. The system of claim 1, wherein the controller is configured to communicate with at least two of the one or more cooling fans via a single channel.

4. The system of claim 1, wherein the controller is configured to communicate with each cooling fan independently.

5. The system of claim 1, wherein the controller is configured to provide a web application that provides the temperature data from the one or more temperature sensors for display on one or more remote devices.

6. The system of claim 5, wherein the web application comprises a graphical user interface.

7. The system of claim 5, wherein the web application comprises a user control configured to receive input for at least one property of the controller.

8. The system of claim 1, wherein the base station enclosure comprises cellular base station equipment, and wherein the controller is configured to receive temperature data indicating a temperature of the cellular base station equipment.

9. The system of claim 1, wherein the processor is further configured to detect an overriding condition present in the base station enclosure and override the fan duty controlled using the proportional and integral control.

10. The system of claim 9, wherein the overriding condition is an excess of hydrogen or smoke present within the base station enclosure.

11. A method comprising:
receiving, by a processor, a signal indicating temperature data sensed by one or more temperature sensors located within a base station enclosure;
controlling, by the processor and using proportional and integral control, a fan duty of one or more cooling fans located within the base station enclosure, based on the temperature data received from the one or more temperature sensors;
detect an overriding condition present in the base station enclosure; and
overriding the fan duty controlled using the proportional and integral control.

12. The method of claim 11, wherein the overriding condition is an excess of hydrogen or smoke present within the base station enclosure.

13. The method of claim 11, wherein the overriding condition is a presence of a person within the base station enclosure.

14. The method of claim 11, wherein the processor is located within the base station enclosure.

15. A system comprising:
a base station enclosure comprising one or more temperature sensors and one or more cooling fans; and
a controller comprising a processor, one or more temperature input ports each communicatively coupled to a respective temperature sensor of the one or more temperature sensors, and one or more fan output ports communicatively coupled to a respective cooling fan of the one or more cooling fans;
wherein the processor is configured to:
receive a signal indicating temperature data sensed by each temperature sensor; and
control a fan duty of each cooling fan based on the received temperature data and using proportional and integral control.

16. The system of claim 15, wherein the controller is configured to communicate with at least two cooling fans of the one or more cooling fans via a single channel.

17. The system of claim 15, wherein the controller comprises a data storage, and wherein the processor is configured to record the temperature data to the data storage.

18. The system of claim 15, wherein the controller comprises a main board and an extension board coupled via an extension port of the main board.

19. The system of claim 15, wherein the base station enclosure comprises cellular base station equipment, and wherein the controller is configured to receive temperature data indicating a temperature of the cellular base station equipment.

20. The system of claim 15, wherein the controller is configured to provide a web application that provides the temperature data from each temperature sensor for display on a remote device.
